(19) United States
(12) Patent Application Publication
(10) Pub. No.: US 2010/0239963 A1
(43) Pub. Date: Sep. 23, 2010

(54) EXPOSURE MASK, EXPOSURE METHOD, AND METHOD OF MANUFACTURING OPTICAL ELEMENT

(75) Inventor: Makoto Ogusu, Shimotsuke-shi (JP)

Correspondence Address: ROSSI, KIMMS & McDOWELL LLP., 20609 Gordon Park Square, Suite 150, Ashburn, VA, 20147, US

(73) Assignee: CANON KABUSHIKI KAISHA, Tokyo (JP)

(21) Appl. No.: 12/729,398

(22) Filed: Mar. 23, 2010

(30) Foreign Application Priority Data
Mar. 23, 2009 (JP) 2009-070003

(51) Int. Cl. G03F 1/00; G03F 7/20

(52) U.S. Cl. 430/5; 430/325; 430/321

(57) ABSTRACT

An exposure mask of the present invention is an exposure mask for patterning a three-dimensional shape on a resist. The exposure mask comprises a first region where a plurality of openings having a first size smaller than a resolution limit of an exposure apparatus are arranged, a second region where a plurality of openings having a second size smaller than the first size are arranged, and a third region where the plurality of openings having the first size and the plurality of openings having the second size are mixed and arranged between the first region and the second region.

### BACKGROUND OF THE INVENTION

1. Field of the Invention

The present invention relates to an exposure mask for patterning a three-dimensional shape on a resist.

2. Description of the Related Art

Commonly, a circuit pattern of a semiconductor device which is manufactured by using a lithography technology is designed by a combination of an opening portion and a light shielding portion formed on a mask. Exposure light transmitted through the mask is irradiated on a resist that is a photo-sensitive material to transfer a mask pattern. As disclosed in Japanese Patent Laid-open No. 2006-106597, recently, a method of generating a light intensity distribution of the exposure light to form an arbitrary shape including a curved surface has been proposed. A mask disclosed in Japanese Patent Laid-open No. 2006-106597 is a binary mask having an opening portion and a light shielding portion, and opening patterns are arranged at a pitch less than a resolution limit of an exposure apparatus to gradually change an exposure amount.

According to such a technology, curved surface shapes can be closely arranged to form an optical element such as a micro lens array. The technology can be widely applied, and for example, the design of the pattern is changed to manufacture a shape having a step at a boundary of the curved surface or the size distribution of the opening portion is changed to manufacture an aspherical surface shape.

However, the segmentation of the control of the transmittance is limited, and the height needs to be changed with finite steps. Especially, in the exposure apparatus using the EUV light (extreme ultraviolet light), the surface roughness required for the surface of the optical element also becomes small. Therefore, the technology of Japanese Patent Laid-open No. 2006-106597 can not sufficiently address the required smoothness. Further, in the technology of Japanese Patent Laid-open No. 2006-106597, the number of the exposure times needed for a multiple exposure is larger, and the number of the masks increases.

### BRIEF SUMMARY OF THE INVENTION

The present invention provides an exposure mask capable of efficiently forming a smooth curved surface.

An exposure mask as one aspect of the present invention is an exposure mask for patterning a three-dimensional shape on a resist. The exposure mask comprises a first region where a plurality of openings having a first size smaller than a resolution limit of an exposure apparatus are arranged, a second region where a plurality of openings having a second size smaller than the first size are arranged, and a third region where the plurality of openings having the first size and the plurality of openings having the second size are mixed and arranged between the first region and the second region.

Further features and aspects of the present invention will become apparent from the following description of exemplary embodiments with reference to the attached drawings.

### BRIEF DESCRIPTION OF THE DRAWINGS

FIG. 1 is a plan view of an exposure mask in Embodiment 1.

FIG. 2 is an existence probability distribution of opening patterns having different sizes from each other in Embodiment 1.

FIG. 3 is an existence probability distribution of opening patterns having different sizes from each other in Embodiment 1.

FIG. 4 is an existence probability distribution of opening patterns having different sizes from each other in Embodiment 1.

FIG. 5 is a plan view of an exposure mask in Embodiment 2.

FIG. 6 is a plan view of an exposure mask in Embodiment 3.

FIG. 7 is a plan view of an exposure mask in Embodiment 4.

FIG. 8 is a plan view of an exposure mask in Embodiment 5.

FIG. 9 is a manufacturing process diagram of a micro mirror array in the present embodiment.

FIG. 10 is a schematic configuration diagram of an exposure apparatus in the present embodiment.

### DETAILED DESCRIPTION OF THE PREFERRED EMBODIMENTS

Exemplary embodiments of the present invention will be described below with reference to the accompanied drawings. In each of the drawings, the same elements will be denoted by the same reference numerals and the duplicate descriptions thereof will be omitted.

### Embodiment 1

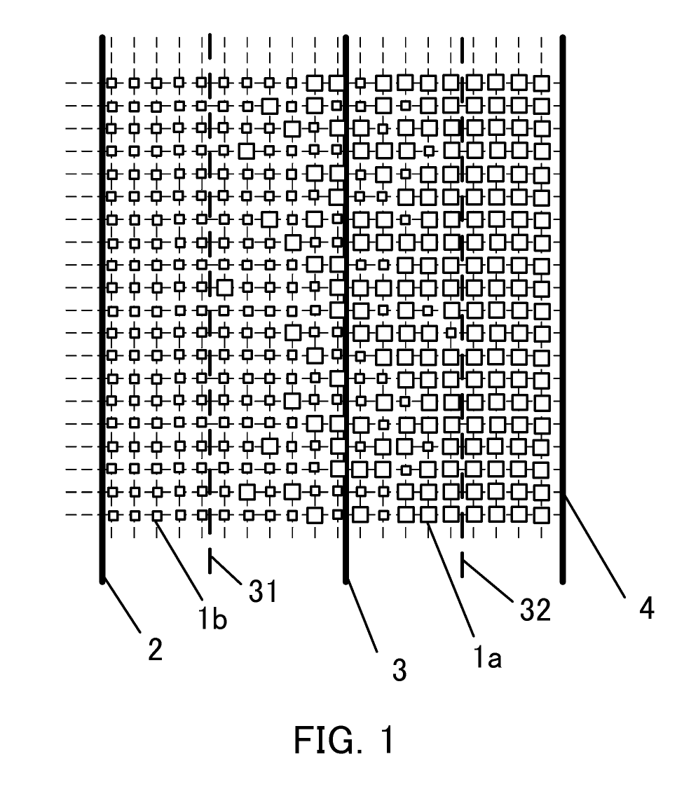

First, Embodiment 1 of the present invention will be described. FIG. 1 is a plan view of an exposure mask in the present embodiment. The exposure mask of the present embodiment is an exposure mask for patterning a three-dimensional shape on a resist. The exposure mask of the present embodiment is especially used for patterning a cylindrical shape on the resist, but the present embodiment is not limited to this. The cylindrical shapes obtained by the exposure mask shown in FIG. 1 have the same height (positioned on a counter line) in an upward and downward direction (in a longitudinal direction) and the heights of the cylindrical shapes change in a right and left direction (in a horizontal direction).

In FIG. 1, reference numerals la and lb denote a plurality of opening patterns (hole patterns) arranged at a pitch smaller than a resolution limit. The opening patterns la and lb are openings having different sizes from each other. The difference of the sizes of the opening patterns la and lb corresponds to the smallest step (for example 2 nm) which is manufacturable by the exposure mask. In the present embodiment, both the opening patterns 1a and 1b are square openings, but each side of the square is different by 2 nm from each other.

Reference numerals 2 to 4 denote quantized boundaries. In a conventional configuration, the quantized boundaries 2 to 4 define boundaries of regions where opening patterns having the same size are arranged in line. Further, the quantized boundaries 2 to 4 are determined in accordance with a known mask pattern designing process. The present embodiment will be described focused on typical two pattern levels. A conventional exposure mask was divided by opening patterns having two different sizes considering the quantized boundary 3 as a boundary. On the other hand in the present embodiment, as shown in FIG. 1, in the vicinity of the quantized boundary 3, a plurality of opening patterns 1a and a plurality of opening patterns lb are mixed and arranged.

In FIG. 1, a region between the quantized boundary 4 and a dotted line 32 is a first region where the plurality of opening patterns la having a first size smaller than a resolution limit of the exposure apparatus are arranged. The region between the quantized boundary 2 and a dotted line 31 is a second region where the plurality of opening patterns 1b having a second size smaller than the first size are arranged. A region between the first region and the second region (a region between the dotted lines 31 and 32) is a third region where the plurality of opening patterns 1a, each of which has the first size, and the plurality of opening patterns 1b, each of which has the second size, are mixed and arranged.

As shown in FIG. 1, any opening pattern 1b which has the second size does not exist in the first region. Further, any opening pattern 1a which has the first size does not exist in the second region. The existence probability of the opening patterns 1a having the first size and the opening patterns 1b having the second size which are arranged in the third region changes in accordance with the height of a three-dimensional shape obtained by patterning the resist.

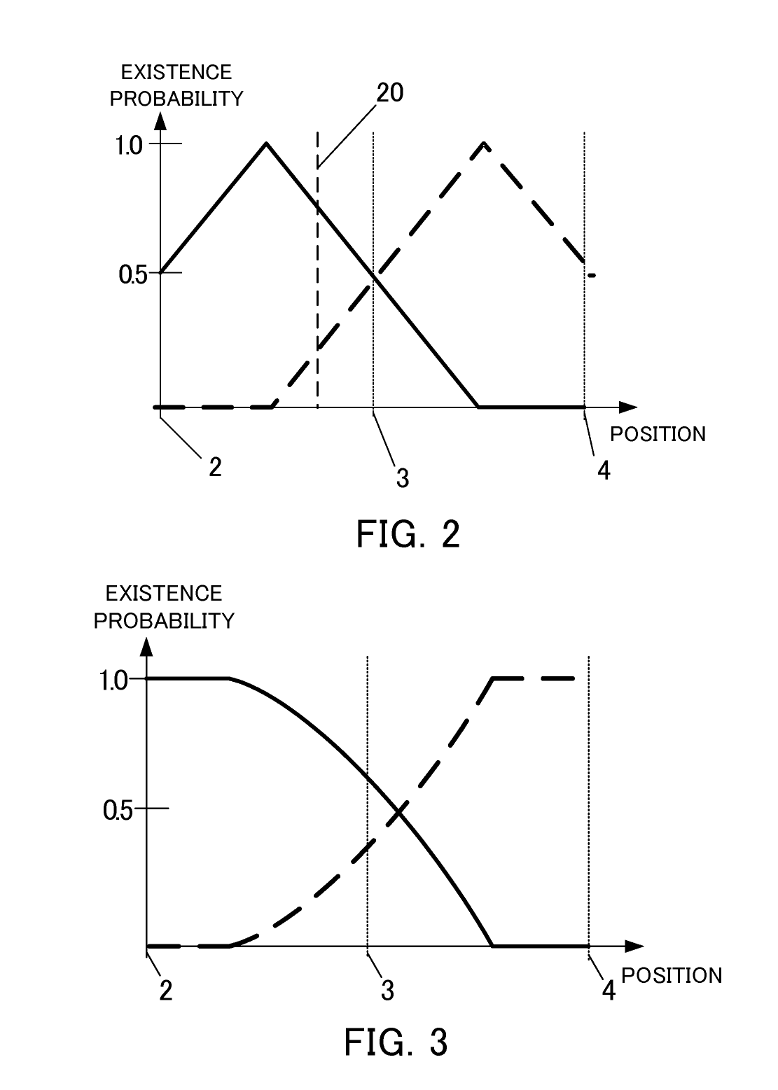

There are a plurality of methods as methods for mixing the opening patterns 1a having the first size and the opening patterns 1b having the second size in the third region. In the present embodiment, as shown in FIG. 2, the existence probabilities of the opening patterns 1a and 1b are defined and random numbers are generated to be compared with the existence probabilities to mix the two kinds of opening patterns 1a and 1b adjacent to each other. FIG. 2 is a relationship diagram of the existence probabilities of the opening patterns 1a and 1b and the horizontal direction position on the exposure mask. The horizontal axis in FIG. 2 is an arbitrary position in the horizontal direction (in the right and left direction) in FIG. 1, and shows the quantized boundaries 2 to 4 on the horizontal axis. A solid line in FIG. 2 indicates the existence probability of the opening pattern 1b having the second size. A dashed line in FIG. 2 indicates the existence probability of the opening pattern 1a having the first size. As described above, the opening pattern 1b having the second size is smaller than the opening pattern 1a having the first size.

In FIG. 2, the positions where the existence probabilities of the opening patterns la having the first size or the opening patterns 1b having the second size is equal to 1 (the center of the quantized boundaries 2 and 3, and the center of the quantized boundaries 3 and 4) correspond to sampling points at the time of designing the exposure mask. The sampling point means an intersection (a point on a contour line) of a line having a constant height and a three-dimensional shape (a surface shape) formed by patterning the resist.

Both the existence probabilities of the opening patterns 1a and 1b are 0.5 on the quantized boundary 3, and the solid line and the dashed line intersect on the quantized boundary 3. The plan view of the exposure mask shown in FIG. 1, for easy understanding, shows a configuration where the opening patterns 1a and 1b having different sizes from each other are mixed only in the vicinity of the quantized boundary 3. Therefore, the existence probability indicating 1 at the sampling point extends up to the quantized boundaries 2 and 4 in a state of maintaining the existence probability of 1 in a case of the solid line and the dashed line, respectively. Actually, however, the quantized regions are continuously provided other than the configuration shown in FIG. 1. In FIG. 2, for easy understanding, a graph of an existence probability at the left side of the quantized boundary 2 and a graph of an existence probability at the right side of the quantized boundary 4 are omitted. Because each omitted graph intersects the solid line or the dashed line on the quantized boundary 2 or 4 in FIG. 2, both the solid line and the dashed line indicate a value of 0.5.

Next, a method of determining sizes of the opening patterns 1a and 1b will be described. The quantized boundaries 2 to 4 are defined as middle points of the sampling points. Virtual meshes are arranged at a pitch smaller than the resolution limit on the exposure mask. The opening patterns 1a and 1b are arranged at intersections of the virtual meshes. In this case, at an intersection of each mesh, the existence probabilities of the opening patterns 1a and 1b are obtained based on a distance of a perpendicular line extending to a quantized boundary. In the present embodiment, a random number between 0 and 1 is generated to obtain the distribution of the existence probabilities of the opening patterns 1a and 1b and compare the existence probabilities.

In FIG. 2, a dotted line 20 indicates a distance from the quantized boundary. In this case, the existence probability indicated by the intersection of the existence probability line of the solid line and the dotted line 20 provides an existence probability of the small-sized opening pattern 1b which mainly exists between the quantized boundaries 2 and 3. When the random number described above is smaller than the existence probability obtained at the intersection with the dotted line 20, the small-sized opening pattern 1b is adopted. On the other hand, when the random number is larger than the existence probability, the large-sized opening la is adopted.

When the opening patterns 1a and 1b having the different sizes from each other are mixed by a method described above, a tone which was unable to be realized by a conventional mask drawing apparatus can be continuously expressed. In the present embodiment, since the existence probabilities of the opening patterns 1a and 1b are defined by straight lines, the area between sampling points are linearly approximated.

Next, an existence probability distribution which is different from the above existence probability distribution that linearly changes will be described with reference to FIG. 3. The existence probability of the opening pattern, which is shown in FIG. 3, changes in a curved line between sampling points. Specifically, the existence probability of the opening pattern 1a having the first size (dotted line) increases so that the increasing rate becomes larger from the quantized boundary 2 to the quantized boundary 3. The existence probability of the opening pattern 1b having the second size (solid line) decreases so that the decreasing rate becomes larger from the quantized boundary 2 to the quantized boundary 3. When such a curve approximation is performed, a slightly higher shape is formed on the quantized boundary 3 as compared with the case where the above straight-line approximation is performed. Therefore, when the vicinity of the quantized boundary 3 is a part of a convex shape, an error from a design value can be reduced as compared with the case of the straight-line approximation.

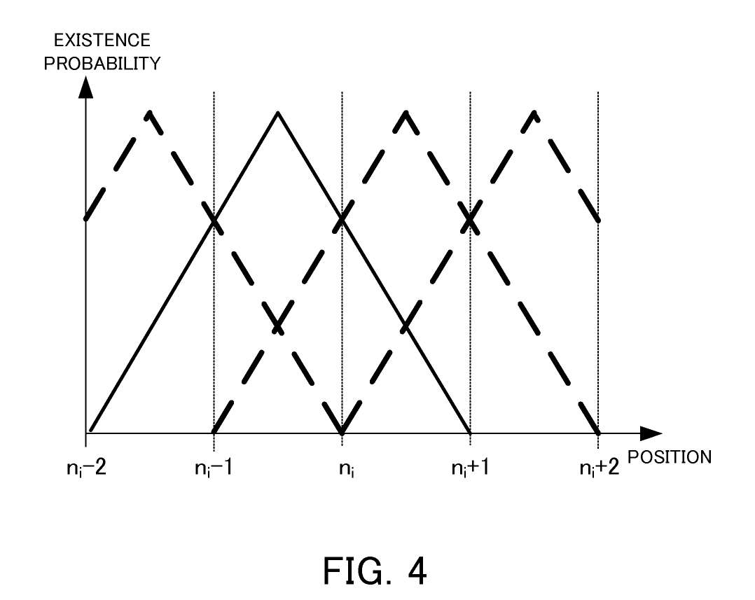

In the embodiment, the mixture region of the opening patterns having different sizes may also be extended to an adjacent region. FIG. 4 is an existence probability distribution when the opening patterns having different sizes are mixed in each of a plurality of adjacent regions. FIG. 4 shows an existence probability distribution at positions on generalized quantized boundaries nᵢ−2, nᵢ−1, nᵢ, nᵢ+1, and nᵢ+2. Thus, a size of the average opening pattern at an arbitrary position is the sum of values obtained by multiplying each existence probability to sizes of three kinds of opening patterns. When the exposure mask is designed, a predetermined correction coefficient is obtained from the sum (the average size of the opening patterns) and a size of an opening pattern actually required to correct each existence probability.

According to the present embodiment, since an existence probability distribution of an opening pattern which corresponds to a relative shape connecting sampling points is formed, a smooth curved surface can be efficiently formed.

### Embodiment 2

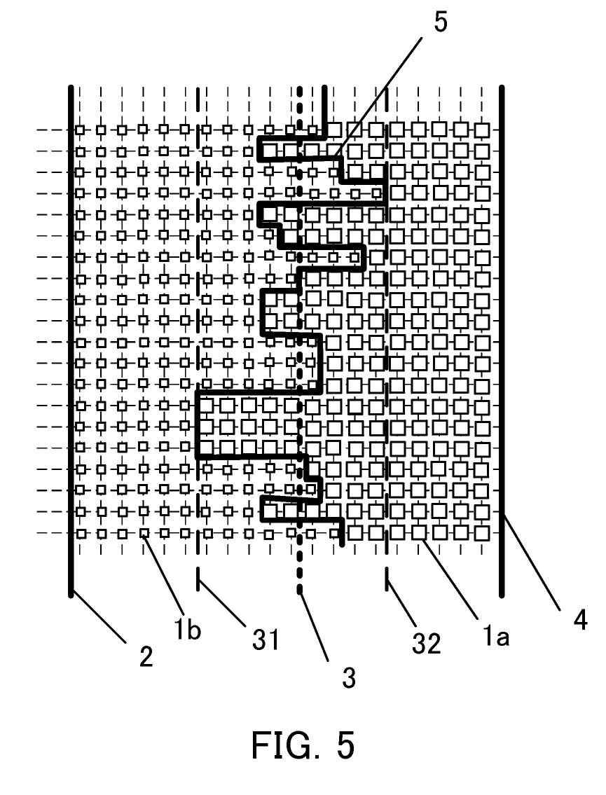

Next, Embodiment 2 of the present invention will be described. FIG. 5 is a plan view of an exposure mask in the present embodiment. The exposure mask of the present embodiment is the same as that of Embodiment 1 in that it is used for pattering a cylindrical shape (a three-dimensional shape) on a resist and has first, second, and third regions.

As shown in FIG. 5, in the present embodiment, opening patterns having the same size are continuously arranged in the third region. However, a position where an opening pattern having a first size and an opening pattern having a second size are adjacent to each other is different in an upward and downward direction (length) and a right and left direction (width). In other words, a boundary 5 where the plurality of opening patterns la having the first size and the plurality of opening patterns lb having the second size are adjacent to each other has nonuniform lengths and widths. Thus, a state where the plurality of opening patterns having different sizes are mixed (in a state where the length and the width of the boundary 5 are nonuniform) with respect to a direction parallel to the quantized boundary 3 is also defined as a mixture of the opening patterns having the first and second sizes.

The patterns are mixed at a pitch finer than a spatial frequency of the resolution limit of the exposure apparatus. When a new quantized boundary is arranged, a straight line orthogonal to the quantized boundary is moved along the quantized boundary. Two quasi-random numbers of the horizontal coordinate position and the existence probability in FIG. 2 are generated for each area where the straight line intersects with the mesh intersection at which the opening pattern is arranged. Only when the area is in a triangle near the quantized boundary 3 formed by the solid line and the dashed line of FIG. 2, the quasi-random numbers are adopted and the quantized boundary is generated at the horizontal coordinate position. As a result, the existence probability distribution of each opening pattern size along the original quantized boundary indicates a distribution shown in FIG. 2. Similarly to the case of Embodiment 1, another existence probability distribution can also be used.

### Embodiment 3

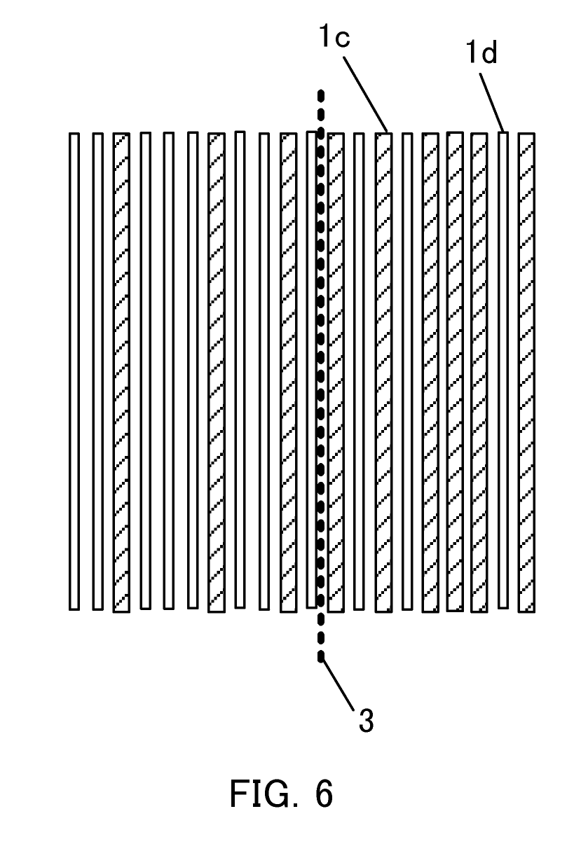

Next, Embodiment 3 of the present invention will be described. FIG. 6 is a plan view of an exposure mask in the present embodiment. The exposure mask of the present embodiment is the same as that of Embodiment 1 in that it is used for patterning a cylindrical shape (a three-dimensional shape) on a resist. In the present embodiment, however, line patterns instead of hole patterns as described in Embodiments 1 and 2 are arranged as opening patterns 1c and 1d having different sizes. In the present embodiment, each of a first size of the opening pattern 1c and a second size of the opening pattern 1d corresponds to a width (a length in a right and left direction) of the line pattern extending in an upward and downward direction of FIG. 6. The line pattern as opening patterns 1c and 1d are suitably used for forming the cylindrical shape.

Thick line patterns more than thin line patterns are arranged at the right side of the quantized boundary 3. On the other hand, thin line patterns more than thick line patterns are arranged at the left side of the quantized boundary 3. Thus, the existence probability of each line pattern changes in a right and left direction in FIG. 6. The exposure mask as described in the present embodiment can also be used to form a smooth curved surface.

### Embodiment 4

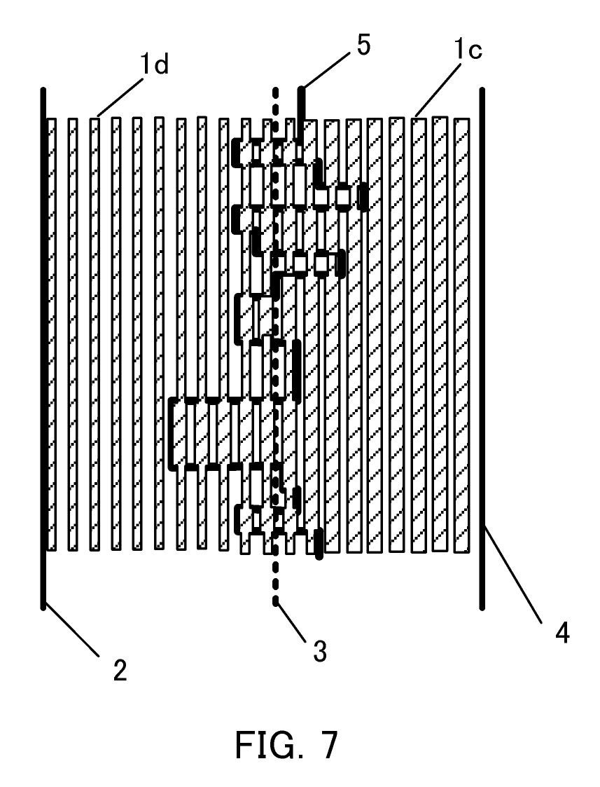

Next, Embodiment 4 of the present invention will be described. FIG. 7 is a plan view of an exposure mask in the present embodiment. The exposure mask of the present embodiment is the same as that of Embodiment 3 in that line patterns are arranged. In the present embodiment, however, widths of specific line patterns change in an upward and downward direction in FIG. 7 (opening patterns having two different sizes are mixed) at an adjacent part (a mixed region) of the opening patterns (line patterns) having the two different sizes. As shown in FIG. 7, in the mixed region, the opening patterns having the same size are continuously arranged in a horizontal direction. However, when these are mixed, the number or the length of the opening patterns arranged in the horizontal direction is not uniform. Therefore, an apparent boundary 5 is formed on a pattern surface of the exposure mask.

In the present embodiment, when the averaging is performed along the quantized boundary 3, the distributions shown in FIG. 2, described in Embodiment 1, is used as existence probabilities of the opening patterns having the two different sizes. However, the present embodiment is not limited to this, and similarly to the case of Embodiment 1, another existence probability distribution may also be used.

### Embodiment 5

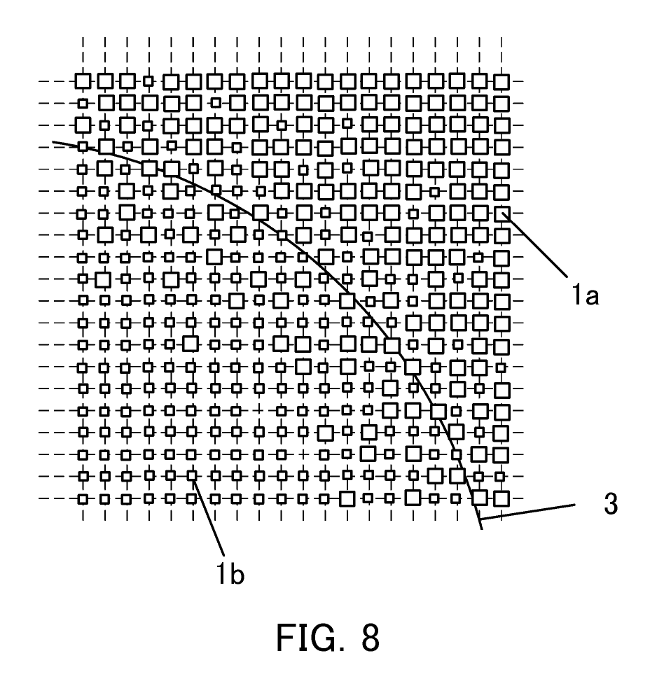

Next, Embodiment 5 of the present invention will be described. FIG. 8 is a plan view of an exposure mask in the present embodiment. Although the exposure mask in each of the above embodiments is used for forming a cylindrical shape, the exposure mask of the present embodiment is used for forming a spherical surface. In a case of the exposure mask for forming the spherical surface, it is often the case that a line connecting sampling points positioned on a concentric circle whose center is a top part of the spherical surface is a quantized boundary.

The plan view shown in FIG. 8 is an enlarged view of a portion forming a part (upper right part) of a spherical surface. The existence probability of the opening patterns 1a having the first size increases from the lower left to the upper right in FIG. 8 with reference to the quantized boundary 3. On the contrary, the existence probability of the opening patterns 1b having the second size increases from the upper right to the lower left. The exposure mask of the present embodiment can efficiently form a smooth spherical surface.

### [Steps of Manufacturing a Micro Mirror Array]

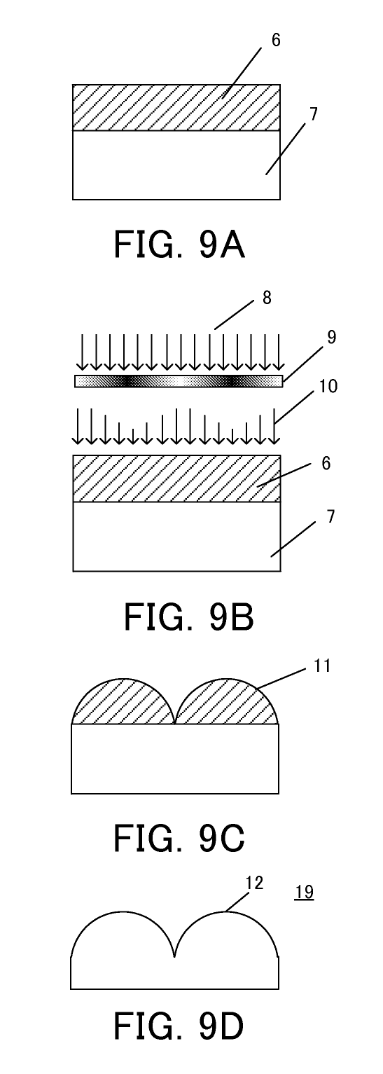

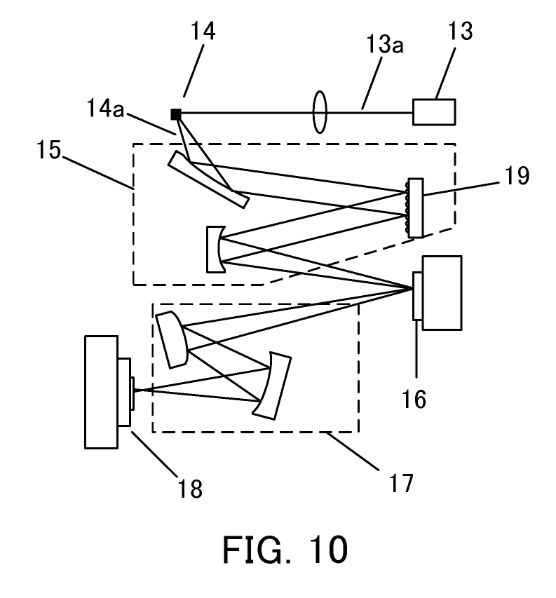

Next, referring to FIGS. 9A to 9D, steps of manufacturing a micro mirror array in the present embodiment will be described. As a substrate 7 of the micro mirror array, for example a substrate made of quartz or silicon having a size of 8 inches φ and a thickness of 1 mm is used. First, a resist 6 (novolac-type positive resist) of around 20 μm is applied to the substrate 7 using a spin coater to perform prebaking (FIG. 9A).

Next, using a mask 9 (the exposure mask described above), an exposure is performed by an exposure apparatus which emits i-line or the like (FIG. 9B). As described above, the mask 9 has transmittances which are different in accordance with its areas. As an exposure method, a contact exposure or a proximity exposure may also be performed. Exposure light 8 passing through the mask 9 becomes light 10 whose intensity (spatial distribution) has been modulated to expose the resist 6. If necessary, post-exposure baking is also performed. Thus, the roll of the resist 6 can be reduced.

Subsequently, the development is performed by using an alkaline developer to form a desired resist pattern 11 on the substrate 7 (FIG. 9C). In the case, the speed of the development of the resist 6 is different in accordance with the areas. Therefore, the resist 6 on the substrate is patterned to be a predetermined three-dimensional shape. After the development, if necessary, post-baking is performed. Next, in an etching condition where the etching selectivity of materials of the resist 6 and the substrate 7 is around 1, the etching of the resist 6 and the substrate 7 is performed to transfer the resist pattern 11 onto the substrate 7 to be able to obtain a micro mirror array 19 having a surface shape 12 (FIG. 9D). As etching used in the embodiment, for example a reactive ion etching (RIE) or a sputter etching may also be used.

### [EUV Exposure Apparatus]

Next, referring to FIG. 10, an EUV exposure apparatus using the micro mirror array described above will be described. In FIG. 10, a plasma 14 is excited by laser light 13a from a pumping laser 13. EUV light 14a emitted from the plasma 14 illuminates an EUV mask 16 via an illumination optical system 15. An optical pattern generated by the EUV mask 16 is imaged on a wafer stage 18 via a projection optical system 17 to form a pattern. In the embodiment, the micro mirror array 19 manufactured by using the exposure mask described above (the mask 9) as an optical element of the illumination optical system 15 is commonly called a fly's eye element and has a role of uniformly illuminating the EUV mask 16.

According to each of the above embodiments, a smooth curved surface i.e. a curved surface having a fine surface roughness can be formed. Therefore, an exposure mask, an exposure method, and a method of manufacturing an optical element which are capable of efficiently forming a smooth curved surface can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-070003, filed on Mar. 23, 2009, which is hereby incorporated by reference herein in its entirety.

What is claimed is:

1. An exposure mask for patterning a three-dimensional shape on a resist, the exposure mask comprising:
a first region where a plurality of openings having a first size smaller than a resolution limit of an exposure apparatus are arranged;
a second region where a plurality of openings having a second size smaller than the first size are arranged; and
a third region where the plurality of openings having the first size and the plurality of openings having the second size are mixed and arranged between the first region and the second region.

2. An exposure mask according to claim 1,
wherein the opening having the second size does not exist in the first region, and
wherein the opening having the first size does not exist in the second region.

3. An exposure mask according to claim 1,
wherein an existence ratio of the plurality of openings having the first size and the plurality of openings having the second size which are arranged in the third region changes in accordance with height of the three-dimensional shape obtained by patterning of the resist.

4. An exposure method of patterning a three-dimensional shape on a resist, the exposure method comprising the steps of:
applying the resist to a substrate; and
exposing the resist using an exposure mask,
wherein the exposure mask is used for patterning the three-dimensional shape on the resist, the exposure mask comprising:
a first region where a plurality of openings having a first size smaller than a resolution limit of an exposure apparatus are arranged;
a second region where a plurality of openings having a second size smaller than the first size are arranged; and
a third region where the plurality of openings having the first size and the plurality of openings having the second size are mixed and arranged between the first region and the second region.

5. A method of manufacturing an optical element comprising the steps of:
patterning a resist on a substrate so as to be a three-dimensional shape by an exposure method, and
etching the resist and the substrate,
wherein the exposure method performs a patterning of the three-dimensional shape on the resist, the exposure method comprising the steps of:
applying the resist to a substrate; and
exposing the resist using an exposure mask,
wherein the exposure mask is used for patterning the three-dimensional shape on the resist, the exposure mask comprising:
a first region where a plurality of openings having a first size smaller than a resolution limit of an exposure apparatus are arranged;
a second region where a plurality of openings having a second size smaller than the first size are arranged; and
a third region where the plurality of openings having the first size and the plurality of openings having the second size are mixed and arranged between the first region and the second region
